(19) United States
(12) Patent Application Publication
(10) Pub. No.: US 2018/0286717 A1
(43) Pub. Date: Oct. 4, 2018

(54) SUBSTRATE PROCESSING APPARATUS AND SUBSTRATE PROCESSING SYSTEM INCLUDING THE SAME

(71) Applicant: EBARA CORPORATION, Tokyo (JP)

(72) Inventors: Katsuhide WATANABE, Tokyo (JP); Itsuki KOBATA, Tokyo (JP)

(21) Appl. No.: 15/935,922

(22) Filed: Mar. 26, 2018

(30) Foreign Application Priority Data
Mar. 31, 2017 (JP) 2017-071563

(51) Int. Cl. H01L 21/67

(52) U.S. Cl. CPC H01L 21/67219

(57) ABSTRACT

Provided is a substrate processing apparatus for making a catalyst and a substrate close to each other or be in contact with each other in the presence of processing liquid to etch a processing target area of the substrate, the substrate processing apparatus including a substrate holder for holding a substrate, and a catalyst holder for holding a catalyst, wherein the catalyst holder comprises a base plate having high rigidity, a piezoelectric element arranged to be adjacent to the base plate, a catalyst holding base having high rigidity arranged to be adjacent to the piezoelectric element, and a catalyst held by the catalyst holding base, and wherein the substrate processing apparatus further comprises a control device for controlling a driving voltage to be applied to the piezoelectric element.

### CROSS-REFERENCE TO RELATED APPLICATION

This application is based upon and claims the benefit of priority of the prior Japanese Patent Application No. 2017-071563, filed on Mar. 31, 2017, the entire content of which is incorporated herein by reference.

### TECHNICAL FIELD

The present invention relates to a substrate processing apparatus and a substrate processing system including the same.

### BACKGROUND ART

A chemical mechanical polishing (CMP) apparatus for polishing the surface of a substrate is known in manufacturing of a semiconductor device. In the CMP apparatus, a polishing pad is stuck to the top surface of a polishing table to form a polishing face. In this CMP apparatus, a polishing target surface of a substrate held by a top ring is pressed against the polishing face, and the polishing table and the top ring are rotated while slurry as polishing liquid is supplied to the polishing face. As a result, the polishing face and the polishing target surface are relatively moved in sliding contact with each other, thereby polishing the polishing target surface.

Here, with respect to a planarization technique containing CMP, polishing target materials have recently diversified, and demand for polishing performance (for example, flatness, polishing damage, and further productivity) becomes stricter. Under such circumstances, new planarization methods have been also proposed, and a catalyst referred etching (hereinafter referred to as “CARE”) method is one of these methods. According to the CARE method, in the presence of processing liquid, reactive species between the processing liquid and a processing target surface are generated from the processing liquid only in the vicinity of a catalyst material, the catalyst material and the processing target surface are made close to each other or brought into contact with each other, whereby it is possible to selectively cause an etching reaction of the processing target surface on a surface of the processing target surface which is close to or in contact with the catalyst material. For example, with respect to a processing target surface having irregularities, convex portions are made close to or brought into contact with the catalyst material, whereby the convex portions can be selectively etched and thus the processing target surface can be planarized (flattened). The CARE method has been initially proposed for planarization of next generation substrate materials such as SiC and GaN for which highly efficient polarization based on CMP has been difficult because these materials are chemically stable (for example, the following PTL 1 and PTL 2). However, it has been recently confirmed that the process is possible even with silicon oxide film, etc., and there is also the possibility of application to present silicon substrate materials.

### CITATION LIST

### Patent Literature

PTL 1: JP2008-121099A

PTL 2: International Publication No. WO2015/159973

### SUMMARY OF INVENTION

### Technical Problem

According to CARE, reactive species are generated from processing liquid only in the vicinity of the surface of a catalyst, and the catalyst and the processing target surface are made close to each other in the nm level or brought into contact with each other, whereby it is possible to selectively cause an etching reaction in this area. Therefore, with respect to a processing target surface having irregularities, convex portions on the processing target surface can be selectively etched. Furthermore, since the etching reaction occurs only at the close or contact portion, the etching speed is influenced by the contact area of the catalyst material. The conventional methods represented by the foregoing literatures have adopted the method of bringing the catalyst material into contact with the processing target surface. For example, in order to efficiently process the processing target surface having irregularities, a method of realizing the close distance (nm level) between the catalyst and the etching target (for example, semiconductor wafer) by using an elastic material (for example, rubber) has been proposed in order to secure uniform contact between the catalyst material and the processing target surface while maintaining selectivity of the irregularities. For example, in PTL 2, a catalyst is disposed on the surface of an elastic member to be brought into contact with a processing target area. The selective contact with or closeness to the convex portions of the processing target is realized by using the property as rigidity of the elastic member, and at the same time the uniform contact between the catalyst and the processing target area is realized by using the property as elasticity of the elastic member. However, in this method, the close state between the catalyst and the processing target surface depends on the characteristic and the surface state of the elastic member (rubber), and it is difficult and limited to control the characteristic and the surface state with high precision in the contact area. In this case, unevenness occurs in the contact state within the contact area between the catalyst (elastic member) and the processing target surface although it depends on the shape of the catalyst surface (elastic material). Particularly, the catalyst at the convex portions on the catalyst (elastic member) side is pressurized more than necessary. When the catalyst and the processing target surface are relatively moved by rotation or the like to introduce processing liquid to the gap between the catalyst and the processing target surface under such a pressurized state, the catalyst surface may wear out, resulting in mechanical deterioration of the catalyst such as peeling or abrasion. Occurrence of the deterioration of the catalyst reduces the lifetime of the catalyst, and the uneven contact state between the catalyst and the processing target surface makes the etching speed uneven in the contact area, so that the etching performance degrades.

The present invention has an object to solve or mitigate at least a part of the foregoing problem.

### Solution to Problem

[First Aspect] According to a first aspect, a substrate processing apparatus for making a catalyst and a substrate close to or be in contact with each other in the presence of processing liquid to etch a processing target area of the substrate is provided. The substrate processing apparatus includes a substrate holder for holding the substrate, and a catalyst holder for holding the catalyst. The catalyst holder includes a base plate having high rigidity, a piezoelectric element arranged to be adjacent to the base plate, a catalyst holding base having high rigidity arranged to be adjacent to the piezoelectric element, and a catalyst held by the catalyst holding base. The substrate processing apparatus further includes a control device for controlling a driving voltage to be applied to the piezoelectric element.

[Second Aspect] According to a second aspect, in the substrate processing apparatus according to the first aspect, the catalyst holder has a first area and a second area, the first area includes a first catalyst, a first catalyst holding base and a first piezoelectric element, the second area includes a second catalyst, a second catalyst holding base and a second piezoelectric element, and the control device is configured to be capable of applying a driving voltage to each of the first piezoelectric element and the second piezoelectric element independently of each other.

[Third Aspect] According to a third aspect, in the substrate processing apparatus according to the first aspect or the second aspect, the control device is configured to apply, to the piezoelectric element, a driving voltage having a frequency for resonating the catalyst holding base and the catalyst.

[Fourth Aspect] According to a fourth aspect, in the substrate processing apparatus according to any one of the first to third aspects, the catalyst holder includes a vibration sensor for monitoring vibration amplitude of the piezoelectric element.

[Fifth Aspect] According to a fifth aspect, the substrate processing apparatus according to any one of the first to fourth aspects further includes a first driving mechanism for moving the catalyst holder in a direction to the substrate holder.

[Sixth Aspect] According to a sixth aspect, the substrate processing apparatus according to any one of the first to fifth aspects further includes a second driving mechanism for moving the catalyst holder in a direction parallel to a substrate holding face of the substrate holder.

[Seventh Aspect] According to a seventh aspect, in the substrate processing apparatus according to the sixth aspect, the movement of the catalyst holder by the second driving mechanism contains at least one of a rotational movement, a rectilinear movement, and a combination movement of the rotational movement and the rectilinear movement.

[Eighth Aspect] According to an eighth aspect, the substrate processing apparatus according to any one of the first to seventh aspects further includes a third driving mechanism for moving the substrate holder in a direction parallel to a substrate holding face of the substrate holder.

[Ninth Aspect] According to a ninth aspect, in the substrate processing apparatus according to the eighth aspect, the movement of the catalyst holder by the third driving mechanism contains at least one of a rotational movement, a rectilinear movement, and a combination movement of the rotational movement and the rectilinear movement.

[Tenth Aspect] According to a tenth aspect, a substrate processing system is provided, and the substrate processing system includes the substrate processing apparatus according to any one of the first to ninth aspects, a cleaning apparatus for cleaning the substrate after the processing in the substrate processing apparatus, a drying apparatus for drying the substrate after the cleaning in the cleaning apparatus, a carrying mechanism for carrying the substrate in the substrate processing system, and a control device for controlling the operations of the substrate processing apparatus, the cleaning apparatus, the drying apparatus and the carrying mechanism.

[Eleventh Aspect] According to an eleventh aspect, the substrate processing system according to the tenth aspect further includes a CMP apparatus for performing CMP processing on the substrate.

### BRIEF DESCRIPTION OF DRAWINGS

FIG. 1 is a block diagram showing the overall configuration of a substrate processing system according to an embodiment;

FIG. 2 is a schematic diagram showing the configuration of a substrate processing apparatus for executing CARE according to an embodiment;

FIG. 3A is a side cross-sectional view which schematically shows the structure of a CARE head according to an embodiment;

FIG. 3B is a side cross-sectional view which schematically shows the structure of the CARE head according to an embodiment;

FIG. 4 is a side cross-sectional view which schematically shows the structure of the CARE head according to an embodiment;

FIG. 5 is a side cross-sectional view which schematically shows a part of the structure of the CARE head according to an embodiment;

FIG. 6 is a side cross-sectional view which schematically shows a part of the structure of the CARE head according to an embodiment;

FIG. 7A is a diagram showing an example of the arrangement of a piezoelectric element when the CARE head is viewed from the catalyst side;

FIG. 7B is a diagram showing an example of the arrangement of the piezoelectric element when the CARE head is viewed from the catalyst side;

FIG. 7C is a diagram showing an example of the arrangement of the piezoelectric element when the CARE head is viewed from the catalyst side;

FIG. 7D is a diagram showing an example of the arrangement of the piezoelectric element when the CARE head is viewed from the catalyst side;

FIG. 8 is a diagram showing an aspect that the CARE head is approached to a processing target area of the substrate and then a driving voltage is applied to the piezoelectric element to bring the catalyst into contact with a processing target surface of the substrate; and

FIG. 9 is a graph showing a signal of a vibration sensor when an AC voltage is applied to the piezoelectric element.

### DESCRIPTION OF EMBODIMENTS

Embodiments of a substrate processing apparatus and a substrate processing system according to the present invention will be described with reference to the accompanying drawings. In the accompanied drawings, the same or similar elements are represented by the same or similar reference signs, and duplicative descriptions on the same or similar elements in the description of each embodiment may be omitted. The features shown in each embodiment may be applied to the other embodiments as long as these features do not contradict one another.

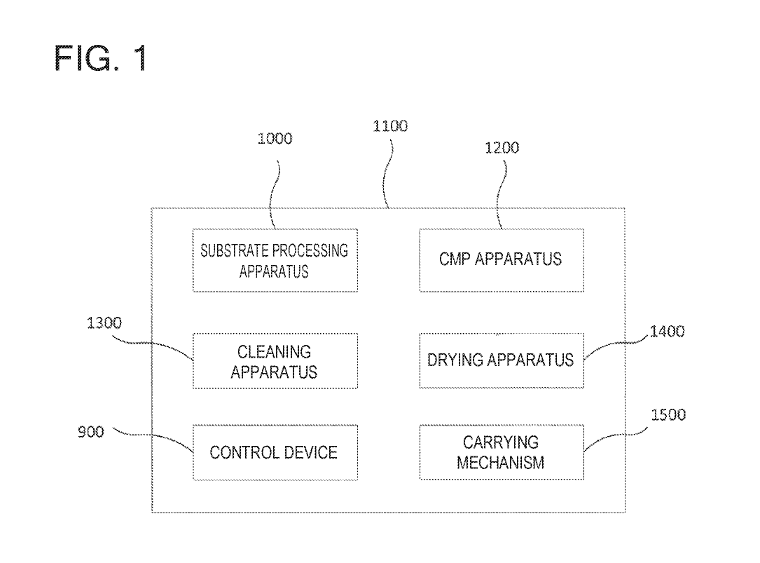

FIG. 1 is a block diagram showing the overall configuration of a substrate processing system 1100 according to an embodiment. As shown in FIG. 1, the substrate processing system 1100 includes a substrate processing apparatus 1000 for executing CARE processing, a CMP apparatus 1200 for executing CMP processing, a cleaning apparatus 1300, a drying apparatus 1400, a carrying mechanism 1500 and a control device 900. The substrate processing apparatus 1000 of the substrate processing system 1100 may be configured as a substrate processing apparatus 1000 that performs CARE and has any feature which will be described in the present specification.

Any CMP apparatus may be used as the CMP apparatus 1200. For example, the CMP apparatus 1200 may be any one or both of a polishing apparatus for polishing a substrate by using a polishing pad having a larger area than a substrate Wf as a processing target, and a polishing apparatus for polishing the substrate Wf by using a polishing pad having a smaller area than the substrate Wf as a processing target.

The cleaning apparatus 1300 is an apparatus for cleaning the processed substrate Wf. The cleaning apparatus 1300 can clean the substrate Wf at any timing. For example, cleaning may be performed after the CARE processing in the substrate processing apparatus 1000, after the polishing in the CMP apparatus. Since any publicly-known cleaning apparatus may be used as the cleaning apparatus 1300, the details thereof are not described in the present specification.

The drying apparatus 1400 is an apparatus for drying the cleaned substrate Wf. Since any publicly-known drying module may be used as the drying apparatus 1400, the details thereof are not described in the present specification.

The carrying mechanism 1500 is a mechanism for carrying a substrate in the substrate processing system 1100, and performs delivery of the substrate Wf among the substrate processing apparatus 1000, the CMP apparatus 1200, the cleaning apparatus 1300 and the drying apparatus 1400. The carrying mechanism 1500 also performs carry-in and carry-out of the substrate Wf into and out of the substrate processing system 1100. Since any publicly-known carrying mechanism can be used as the carrying mechanism 1500, the details thereof are not described in the present specification.

The control device 900 controls the operations of each apparatus in the substrate processing system 1100. The control device 900 may be configured by a general all-purpose computer including hardware pieces such as a storage device, an input/output device, a memory and CPU, a dedicated purpose computer or the like. The control device 900 may be configured by a single hardware piece or a plurality of hardware pieces.

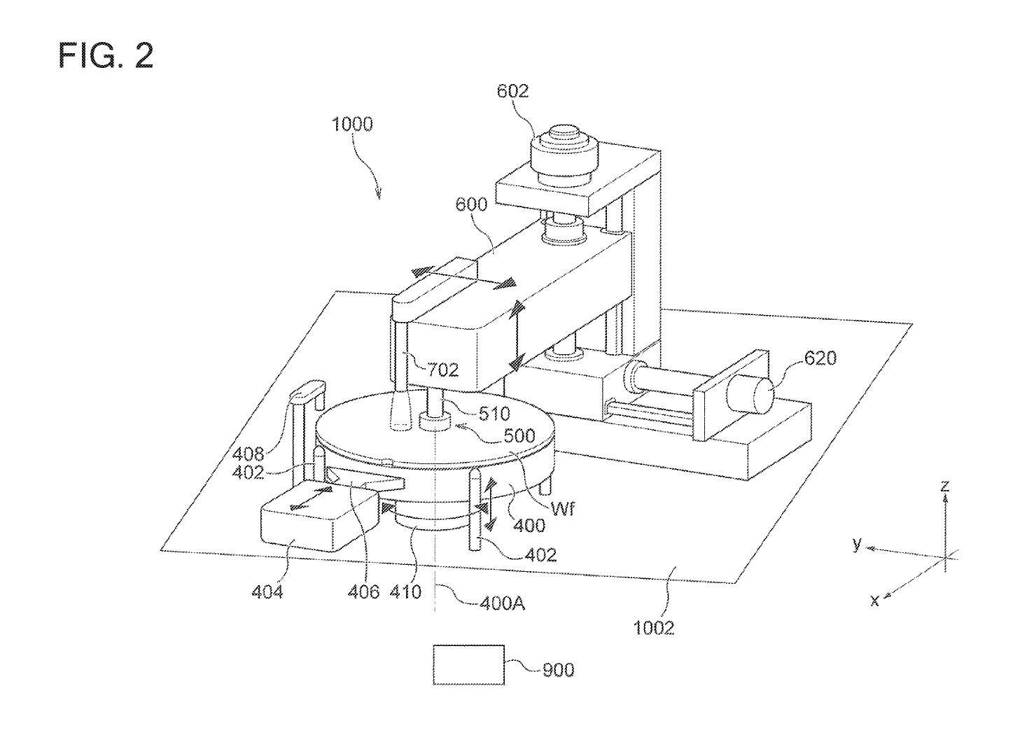

FIG. 2 is a schematic diagram showing the configuration of the substrate processing apparatus 1000 for executing CARE according to an embodiment. As shown in FIG. 2, the substrate processing apparatus 1000 is configured on a base face 1002. The substrate processing apparatus 1000 may be configured as an independent single apparatus or configured as a module which is a part of the substrate processing system 1100 containing the CMP apparatus 1200 in addition to the substrate processing apparatus 1000 (see FIG. 1). The substrate processing apparatus 1000 is arranged in a housing (not shown). The housing includes an exhaust mechanism (not shown), and is configured so that polishing liquid, etc. is not exposed to the outside of the housing during polishing processing.

As shown in FIG. 2, the substrate processing apparatus 1000 includes a stage 400 for holding a substrate Wf with the substrate Wf placed face up as a substrate holder. In an embodiment, the substrate Wf can be placed on the stage 400 by the carrying mechanism 1500. The substrate processing apparatus 1000 shown in FIG. 2 includes four vertically-movable lift pins 402 around the stage 400, and the substrate Wf can be received onto the four lift pins 402 from the carrying mechanism 1500 while the lift pins 402 are set to be lifted up. After the substrate Wf is placed on the lift pins 402, the lift pins 402 descend to a substrate delivery position to the stage 400, whereby the substrate Wf is temporarily placed on the stage. Therefore, the substrate Wf can be positioned within an area which is limited to the inside of the four lift pins 402. However, when positioning of higher precision is required, the substrate Wf may be positioned at a predetermined position on the stage 400 specially by a positioning mechanism 404. In the embodiment shown in FIG. 1, it is possible to position the substrate Wf by a positioning pin (not shown) and a positioning pad 406. The positioning mechanism 404 includes the positioning pad 406 movable in a planar direction of the substrate Wf. Plural positioning pins (not shown) are provided on the opposite side to the positioning pad 406 with respect to the stage 400. The positioning pad 406 is pressed against the substrate Wf while the substrate Wf is placed on the lift pins 402, whereby the substrate Wf can be positioned by the positioning pad 406 and the positioning pins. After the substrate Wf has been positioned, the substrate Wf is fixed onto the stage 400, and then the lift pins 402 are caused to descend to place the substrate Wf on the stage 400. The stage 400 may be configured so as to fix Wf on the stage 400, for example, by vacuum suction. The substrate processing apparatus 1000 includes a detector 408. The detector 408 serves to detect the position of the substrate Wf placed on the stage 400. For example, the detector 408 can detect the position of the substrate Wf on the stage 400 by detecting a notch or orientation flat formed on the substrate Wf, or an outer peripheral portion of the substrate. Any point of the substrate Wf can be specified based on the position of the notch or orientation flat, thereby enabling a desired area to be processed. Since position information of the substrate Wf on the stage 400 (for example, a deviation from an ideal position) is obtained based on the position information of the outer peripheral portion of the substrate, the movement position of the CARE head 500 may be corrected based on the above information by the control device 900. When the substrate Wf is released from the stage 400, the lift pins 402 are moved from the stage 400 to a substrate receiving position, and then the vacuum suction of the stage 400 is released. Then, after the lift pins 402 are ascended to move the substrate Wf to the substrate delivery position to the carrying mechanism 1500, the carrying mechanism 1500 is enabled to receive the substrate Wf on the lift pins 402. Thereafter, the substrate Wf can be carried to any place for subsequent processing by the carrying mechanism 1500.

The stage 400 of the substrate processing apparatus 1000 includes a rotation driving mechanism 410, and is configured to be capable of making a rotational movement around a rotation axis 400A. Here, “rotational movement” means continuous rotation in a fixed direction, and a movement in a circumferential direction (containing reciprocating movement) in a predetermined angular range. As another embodiment, the stage 400 may have a moving mechanism for applying a linear movement to the held substrate Wf. For example, a so-called XY stage may be used as the moving mechanism for applying the rectilinear movement.

The substrate processing apparatus 1000 shown in FIG. 2 includes a CARE head 500 as a catalyst holder. The substrate processing apparatus 1000 includes a holding arm 600 for holding the CARE head 500. Furthermore, the substrate processing apparatus 1000 includes a vertical driving mechanism 602 for moving the holding arm 600 in a direction vertical to the surface of the substrate Wf (z-direction in FIG. 2). The CARE head 500 and the catalyst 516 are movable in the direction vertical to the surface of the substrate Wf together with the holding arm 600 by the vertical driving mechanism 602. The vertical driving mechanism 602 is a coarse-adjustment driving mechanism for approaching the CARE head 500 to the substrate Wf when the substrate Wf is subjected to the CARE processing. In the embodiment shown in FIG. 2, the vertical driving mechanism 602 is a mechanism using a motor and a ball screw, but as another embodiment, a pneumatic or hydraulic driving mechanism or a driving mechanism using a spring may be used.

The substrate processing apparatus 1000 shown in FIG. 2 further includes a lateral driving mechanism 620 for moving the holding arm 600 in a lateral direction (y-direction in FIG. 2). The CARE head 500 and the catalyst 516 are movable in the lateral direction together with the holding arm 600 by the lateral driving mechanism 620. The lateral direction (y-direction) is a direction parallel to the surface of the substrate Wf. In the embodiment shown in FIG. 2, the lateral driving mechanism 620 is configured to move the holding arm 600 integrally with the vertical driving mechanism 602. As described above, the stage 400 of the substrate processing apparatus 1000 is capable of moving the substrate Wf in a direction parallel to the processing surface of the substrate Wf. Accordingly, the CARE head 500 can be moved to any position on the substrate Wf by appropriately operating the moving mechanism of the stage 400 and the lateral driving mechanism 620 of the holding arm 600.

The substrate processing apparatus 1000 of the embodiment shown in FIG. 2 includes a processing liquid supply nozzle 702. The processing liquid supply nozzle 702 is in fluid communication with a supply source for processing liquid used for the CARE processing. In the substrate processing apparatus 1000 according to the embodiment shown in FIG. 2, the processing liquid supply nozzle 702 is held by the holding arm 600. Therefore, the processing liquid can be efficiently supplied to only the processing area on the substrate Wf via the processing liquid supply nozzle 702. The processing liquid may be supplied from the inside of the CARE head 500 via the inside of the CARE head 500 onto the substrate Wf. In this case, a supply passage for the processing liquid is provided inside a shaft 510 and the CARE head 500, and the processing liquid supply nozzle 702 is provided to the CARE head 500. For example, a structure disclosed in PTL 2 (wO2015/159973) may be adopted as the CARE head equipped with a pipe line for supplying the processing liquid from the shaft 510 to the surface of the catalyst 516.

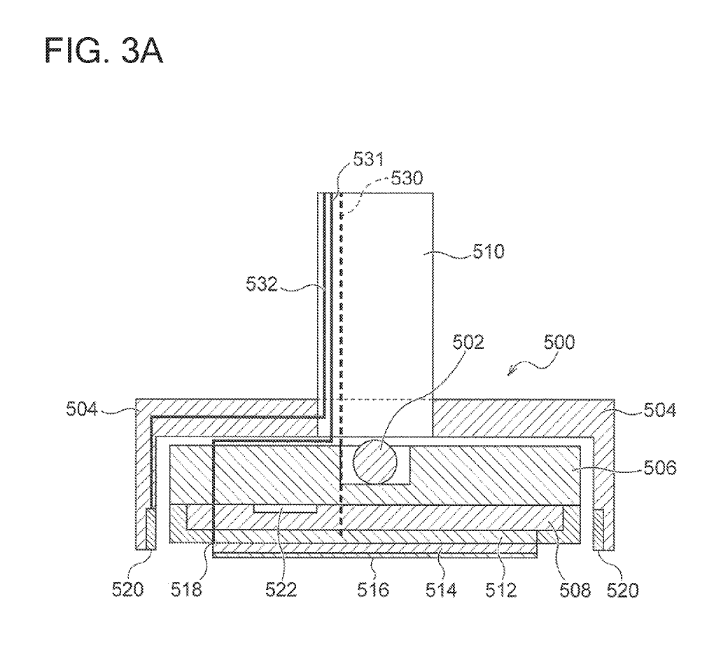

FIG. 3A is a side cross-sectional view which schematically shows the structure of the CARE head 500 according to an embodiment. In the embodiment shown in FIG. 3A, the CARE head 500 is linked to the shaft 510 via a gimbal mechanism 502 (for example, spherical plain sleeve bearing). The shaft 510 is linked to the holding arm 600 as shown in FIG. 2. The CARE head 500 may be rotated by a rotating motor (not shown). As shown in FIG. 3A, the CARE head 500 includes an outer peripheral member 504. The outer peripheral member 504 may be configured in a substantially cylindrical shape which is closed at one end portion thereof.

A head main body 506 is arranged inside the outer peripheral member 504. A base plate 508 is arranged at the lower side of the head main body 506. The base plate 508 is detachably fitted to the head main body 506 by a screw or the like. The base plate 508 is formed of, for example, a high-rigidity material having machinability of 50 GPa or more, preferably 100 GPa or more like metal materials, and an excellent surface-finished state in order to realize a flat surface and prevent deformation of a piezoelectric element 512 described later due to reaction force when the piezoelectric element operates. The base plate 508 may be formed of, for example, ceramics, stainless steel (SUS) or the like.

The piezoelectric element 512 is provided on the lower surface of the base plate 508. The piezoelectric element 512 may be fixed to the lower surface of the base plate 508, for example by adhesive agent or the like. A wire 530 for applying a driving voltage is connected to the piezoelectric element 512. The piezoelectric element 512 is arranged so as to expand/contract in a direction vertical to the lower surface of the base plate 508 upon application of the driving voltage thereto. The maximum amount of the expansion/contraction of the piezoelectric element 512 may be set to about several tens μm to 100 μm in the direction vertical to the lower surface of the base plate 508, but it is desirable that the resolution of the expansion/contraction of the piezoelectric element 512 is equal to 10 nm or less. As described above, the base plate 508 is detachable from the head main body 506. Therefore, the base plate 508 is preferably configured so that electrical wiring 530 to the piezoelectric element 512 is established when the base plate 508 is fitted to the head main body 506. A contact probe or the like for the electrical wiring 530 to the piezoelectric element 512 may be used (see WO2015/159973 or the like).

A catalyst holding base 514 is provided at the lower side of the piezoelectric element 512. It is desirable that the catalyst holding base 514 is formed of metal material from the viewpoint of maintaining the surface roughness and the shape accuracy even after the catalyst is applied, maintaining the strength to the deformation caused by the piezoelectric element 512 and application of the voltage to the catalyst. For example, the catalyst holding base 514 may be formed of metal foil having a thickness of 100 μm or less such as SUS foil.

The catalyst 516 is provided to the lower surface of the catalyst holding base 514. The catalyst 516 may be formed on the surface of the catalyst holding base 514 by vapor deposition, for example. A physical deposition method such as resistance heating type deposition or sputtering deposition, and a chemical deposition method such as CVD are known as a film forming method of the catalyst 516. Furthermore, the catalyst 516 may be formed on the catalyst holding base 514 by another film forming method such as electroplating or electroless plating. The thickness of the catalyst 516 is desired to be in the range from 100 nm to several tens μm. The reason for this is as follows. When the catalyst comes into contact with the substrate and also makes a relative movement, the catalyst deteriorates due to abrasion. Therefore, when the thickness of the catalyst is extremely small, the exchange frequency of the catalyst increases. A plate-like catalyst 516 may be fixed to the catalyst holding base 514. Furthermore, the catalyst holding base 514 may be impregnated in solution containing the catalyst to form a layer of the catalyst 516 on the surface of the catalyst holding base 514.

FIG. 3B is a side cross-sectional view which schematically shows the structure of the CARE head 500 according to an embodiment. In the embodiment shown in FIG. 3B, the CARE head 500 is linked to the shaft 510. The shaft 510 is linked to the holding arm 600 as shown in FIG. 2. The CARE head 500 may be rotatable by a rotating motor (not shown). As shown in FIG. 3B, the CARE head 500 includes the outer peripheral member 504. The outer peripheral member 504 may be configured in a substantially cylindrical shape which is closed at one end portion thereof. The shaft 510 is fitted to the outer peripheral member 504. In the embodiment shown in FIG. 3B, the base plate 508 is connected to the head main body 506 via a spring 550. As described later, when an AC voltage as the driving voltage is applied to the piezoelectric element 512 to vibrate the piezoelectric element 512 so that the catalyst holding base 514 and the catalyst 516 vibrate, the vibration is attenuated by the spring 550, whereby the vibration can be prevented from propagating to the shaft 510 and the holding arm 600. In the embodiment of FIG. 3B, the spring 550 is used as vibration attenuating means, but any other vibration attenuating means such as an elastic member like damping rubber or the like may be used as another embodiment.

As shown in FIGS. 3A and 3B, the CARE head 500 includes a catalyst electrode 518 so as to enable application of a voltage to the catalyst 516. The catalyst electrode 518 is electrically connected to the catalyst 516 or the catalyst holding base 514. The catalyst electrode 518 is connected to a wire 531 via the CARE head 500 and the shaft 510, and configured so that the electrical wiring 531 to the catalyst electrode 518 is established when the base plate 508 is fitted to the head main body 506. The outer peripheral member 504 is provided with a counter electrode 520. The counter electrode 520 has an annular shape. The counter electrode 520 is connected to a wire 532 via the CARE head 500 and the shaft 510. The catalyst electrode 518 and the counter electrode 520 are wired with the wires 531 and 532 via the CARE head 500, and connected to a power source (not shown). Therefore, the catalyst 516 and the counter electrode 520 can be electrically connected to each other via the processing liquid. The activation state of the catalyst 516 can be controlled by applying a voltage to the catalyst 516, thereby changing the etching speed of the substrate Wf. In FIGS. 3A and 3B, the counter electrode 520 is arranged in the CARE head 500, but may be arranged not inside the CARE head 500, but outside the CARE head 500 because it is required only that the catalyst 516 and the counter electrode 520 are electrically connected to each other via the processing liquid.

As described above, the substrate processing apparatus 1000 includes the vertical driving mechanism 602 for approaching the CARE head 500 to the substrate Wf. The vertical driving mechanism 602 moves the CARE head 500 so that the catalyst 516 is close to the surface of the substrate Wf. Thereafter, the driving voltage is applied to the piezoelectric element 512 to minutely control the distance between the catalyst 516 and the substrate Wf.

The CARE head 500 includes a vibration sensor 522. The vibration sensor 522 serves to detect the vibration amplitude when the driving voltage is applied to make the piezoelectric element 512 vibrate. In general, a piezoelectric type, an electrostatic capacitance type, an eddy current type, etc. are known for the vibration sensor. In the embodiment shown in FIG. 3A, the vibration sensor 522 is a piezoelectric type sensor, and embedded in the base plate 508 or the head main body 506. As described later, when the AC voltage as the driving voltage is applied to the piezoelectric element 512 to vibrate the piezoelectric element 512 so that the catalyst holding base 514 and the catalyst 516 vibrate, variation of the vibration amplitude can be monitored by monitoring variation of reaction force to the base plate 508 or the head main body 506 which is caused by the contact or non-contact between the catalyst 516 and the substrate Wf. In the embodiment of FIG. 3B, the vibration sensor 522 is an electrostatic capacitance type or eddy current type sensor, and the variation of the vibration amplitude can be monitored by monitoring the distance between the base plate 508 and the head main body 506. The vibration sensor 522 may be provided at another position insofar as the amplitude displacement corresponding to the vibration of the piezoelectric element 512 can be detected.

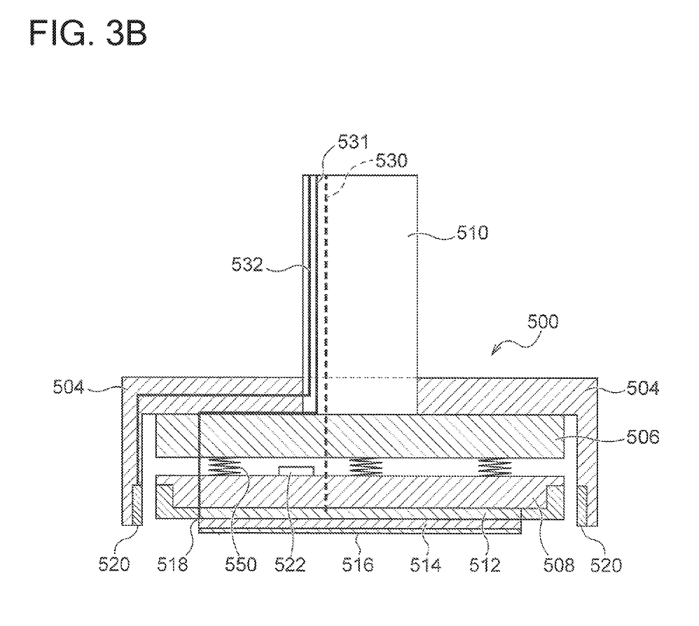

FIG. 4 is a side cross-sectional view which schematically shows the structure of the CARE head 500 according to an embodiment. The CARE head 500 shown in FIG. 4 may be configured to have the same structure as the CARE head 500 shown in FIG. 3 except that the piezoelectric element 512, the catalyst holding base 514 and the catalyst 516 are respectively divided into plural areas. As shown in FIG. 4, plural piezoelectric elements 512 are fitted to the base plate 508. The catalyst holding base 514 is fitted to the lower surface of each piezoelectric element 512, and the catalyst 516 is provided to the lower surface of the catalyst holding base 514. As shown in FIG. 4, a wire 531 for applying a voltage is connected to each catalyst 516. A wire 530 for independently applying the driving voltage is connected to each piezoelectric element 512. Therefore, the contact state or the close distance between each piezoelectric element 512 and the substrate Wf can be independently controlled by controlling the driving voltage to be applied to each piezoelectric element 512. Furthermore, even when the height of the surface of the catalyst 516 is uneven among the respective areas due to processing precision or the like, the catalysts 516 in the respective areas can be evenly brought into contact with or made evenly close to the substrate Wf by controlling the driving voltage to be applied to each piezoelectric element 512.

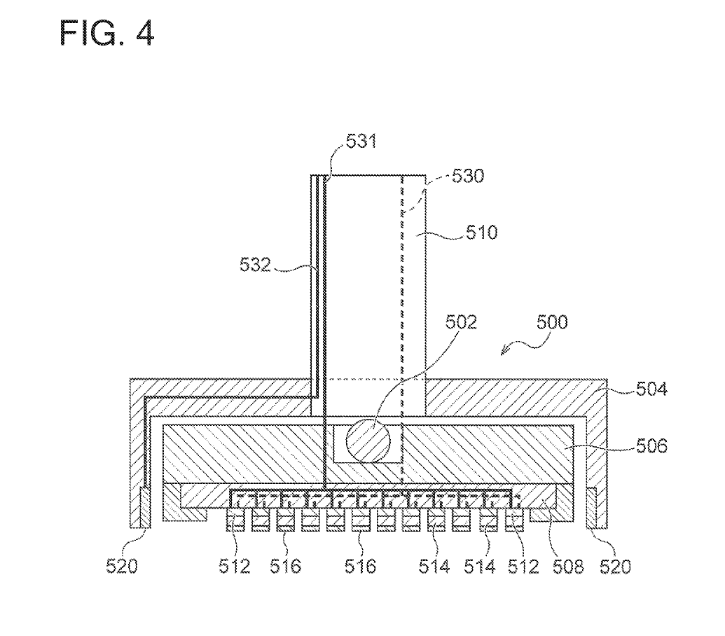

FIG. 5 is a side cross-sectional view which schematically shows a part of the structure of the CARE head 500 according to an embodiment. FIG. 5 shows the base plate 508, the piezoelectric element 512, the catalyst holding base 514 and the catalyst 516 of some area in the CARE head 500, and also schematically shows the substrate Wf to be processed. It may be said that FIG. 5 also shows an example of one area out of the plural areas shown in FIG. 4 into which the piezoelectric element 512, the catalyst holding base 514 and the catalyst 516 are respectively divided. The embodiment shown in FIG. 5 may be configured so that one base plate 508 is provided for the whole CARE head 500, and plural piezoelectric elements 512 are fitted to the lower side of the base plate 508. In the embodiment shown in FIG. 5, the catalyst holding base 514 is configured in a truncated conical shape or truncated pyramid shape, and arranged with the vertex thereof facing the substrate Wf. Therefore, the contact area between the catalyst 516 disposed on the surface of the catalyst holding base 514 and the substrate Wf can be reduced. For example, when a processing target area of the substrate WF as a processing target is a minute area like an internal part of a chip manufactured in a plane of a semiconductor substrate, it is effective that the catalyst 516 has a minute contact area as in the case of the embodiment of FIG. 5. FIG. 5 shows a case where a convex portion exists at a part of a processing target film formed on the substrate Wf and the convex portion is planarized by CARE as an example. Furthermore, in the embodiment shown in FIG. 5, each piezoelectric element 512 may be configured to be capable of applying the driving voltage independently of the other piezoelectric elements 512. Still furthermore, in the embodiment shown in FIG. 5, the catalyst 516 is configured so that a voltage can be applied to the catalyst 516 independently of the other catalysts 516.

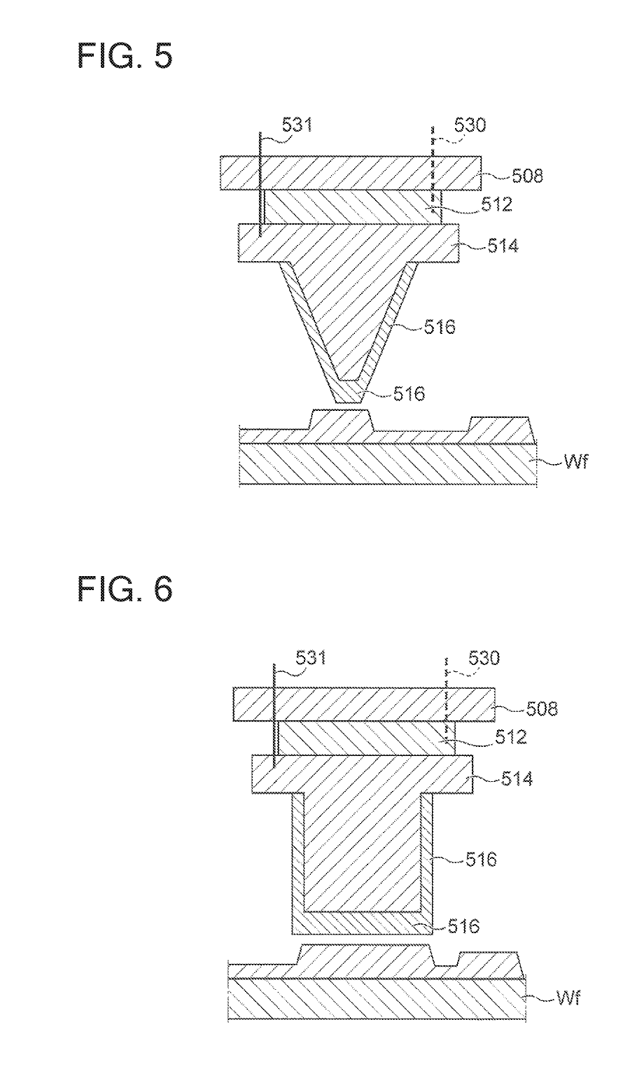

FIG. 6 is a side cross-sectional view which schematically shows a part of the structure of the CARE head 500 according to an embodiment. FIG. 6 shows the base plate 508, the piezoelectric element 512, the catalyst holding base 514 and the catalyst 516 of some area in the CARE head 500, and also schematically shows the substrate Wf to be processed. It may be also said that FIG. 6 shows an example of one area out of the plural areas shown in FIG. 4 into which the piezoelectric element 512, the catalyst holding base 514 and the catalyst 516 which are respectively divided. The embodiment shown in FIG. 6 may be configured so that one base plate 508 is provided for the whole CARE head 500, and the plural piezoelectric elements 512 are fitted to the lower side of the base plate 508. In the embodiment shown in FIG. 6, the catalyst holding base 514 may be configured in a cylindrical shape or prismatic shape, and is arranged so that one end portion thereof faces the substrate Wf. In the embodiment of FIG. 6, the catalyst holding base 514 and the contact area of the catalyst 516 disposed on the surface of the catalyst holding base 514 with the substrate Wf can be reduced in the same way as the embodiment of FIG. 5. For example, when a processing target area of the substrate WF as a processing target is a minute area like an internal part of a chip manufactured in a plane of a semiconductor substrate, it is effective that the catalyst 516 has a minute contact area as in the case of the embodiment of FIG. 6. FIG. 6 shows a case where a convex portion exists at a part of a processing target film formed on the substrate Wf and the convex portion is planarized by CARE as an example. In the embodiments shown in FIGS. 5 and 6, the shape of the catalyst holding base 514 may be appropriately changed according to the area of the processing target area of the substrate Wf to be processed. Furthermore, in the embodiment shown in FIG. 6, each piezoelectric element 512 can be configured so that the driving voltage can be applied to the piezoelectric element 512 independently of the other piezoelectric elements 512. Still furthermore, in the embodiment shown in FIG. 6, the catalyst 516 may be configured so that the voltage can be applied to the catalyst 516 independently of the other catalysts 516.

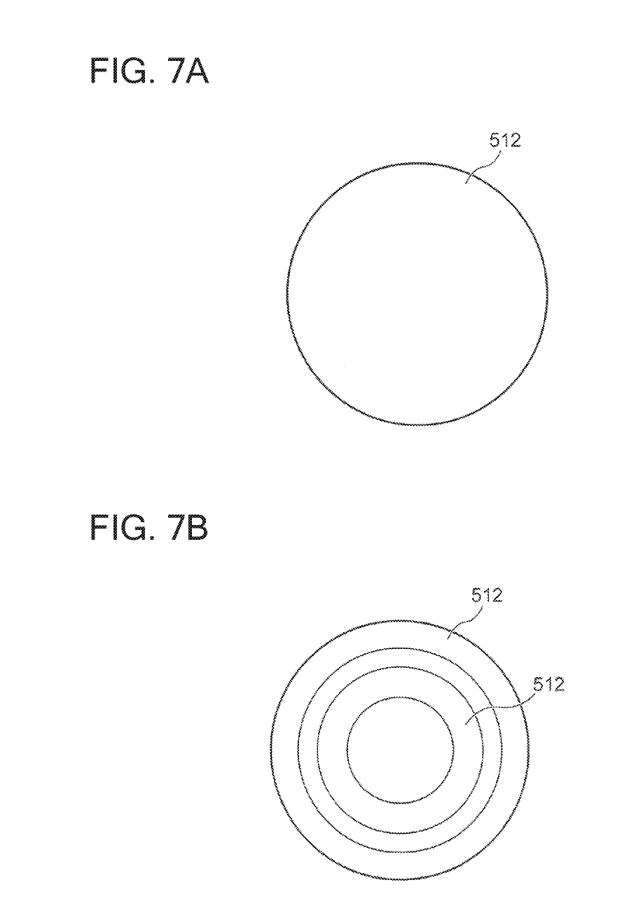

FIGS. 7A to 7D are diagrams showing an example of the arrangement of a piezoelectric element(s) 512. FIG. 7A is a diagram when the CARE head 500 is viewed from the catalyst side. However, FIG. 7A shows only the piezoelectric element 512 fitted to the base plate 508, and the other structure is omitted from the illustration. In FIG. 7A, only one disc-shaped piezoelectric element 512 is arranged on a circular base plate 508. FIG. 7B is a diagram when the CARE head 500 is viewed from the catalyst side. However, in FIG. 7B, only piezoelectric elements 512 fitted to the base plate 508 are shown, and the other structure is omitted. In FIG. 7B, a circular piezoelectric element 512 is arranged at the center of the circular base plate 508, and plural annular piezoelectric elements 512 are concentrically arranged outside the circular piezoelectric elements 512. FIG. 7C is a diagram when the CARE head 500 is viewed from the catalyst side. However, FIG. 7C shows only piezoelectric elements 512 fitted to the base plate 508, and the other structure is omitted. In FIG. 7C, plural square piezoelectric elements 512 are arranged in a lattice form on the circular base plate 508. FIG. 7D is a diagram when the CARE head 500 is viewed from the catalyst side. However, FIG. 7D shows only piezoelectric elements 512 fitted to the base plate 508, and the other structure is omitted. In FIG. 7D, plural circular piezoelectric elements 512 are arranged in a lattice form on the circular base plate 508. FIGS. 7A to 7D shows examples of the arrangement pattern of the piezoelectric elements 512 in the CARE head 500, and the shapes of the catalyst holding base 514 and the catalyst 516 which are fitted to the lower side of each piezoelectric element 512 are arbitrary. For example, the catalyst holding base 514 and the catalyst 516 of the embodiments shown in FIGS. 5 and 6 may be applied. In the embodiments shown in FIGS. 7A to 7D, since the piezoelectric element 512 is divided into plural areas, the driving voltage may be configured to be independently applied to each piezoelectric element 512 for each area. With respect to the arrangement of these piezoelectric elements 512, it may be basically appropriately determined based on the shape of the processing target area. For example, when the processing target area has a distribution in the radial direction of the substrate Wf, the concentric arrangement of the piezoelectric elements as shown in FIG. 7B is desired, and when processing is performed on each chip of each substrate Wf, the piezoelectric element 512 arranged in FIGS. 7C, 7D and the catalyst holding base 514 and the catalyst 516 arranged at the lower side of the piezoelectric element 512 may be configured in a chip-size.

The CARE processing using the substrate processing apparatus 1000 disclosed in the present specification and the substrate processing system 1100 containing the same will be described below. As described above, the substrate processing apparatus 1000 and the substrate processing system 1100 have a control device 900, and each element of the substrate processing apparatus 1000 and the substrate processing system 1100 may be configured to be controllable by the control device 900.

First, the substrate Wf as a processing target is placed on the stage 400. The CARE head 500 as the catalyst holder is moved to a processing target area on the substrate Wf. At this time, the CARE head 500 can be moved to the processing target area of the substrate Wf by combing movements such as the movement of the arm 600, the rotation of the stage 400, etc. The surface state (for example, film thickness, etc.) of the substrate Wf may be detected in advance to determine the position of the processing target area. As described with reference to FIG. 1, the substrate processing apparatus 1000 includes the detector 408 to be capable of specifying any point of the substrate Wf, thereby enabling a desired area to be processed. A processing condition may be determined from the difference between information obtained from the processing target area and a target value of the substrate processing.

When the CARE head 500 has been moved to the processing target position on the substrate Wf, the CARE head 500 is moved in the direction vertical to the surface of the substrate Wf to make the catalyst 516 close to the processing target area of the substrate Wf. At this time, no driving voltage is applied to the piezoelectric element 512 of the CARE head 500 so that the piezoelectric element 512 does not operate. The catalyst 516 is moved so that the distance between the surface of the catalyst 516 and the surface of the processing target area of the substrate Wf is within a movement range based on the piezoelectric element 512.

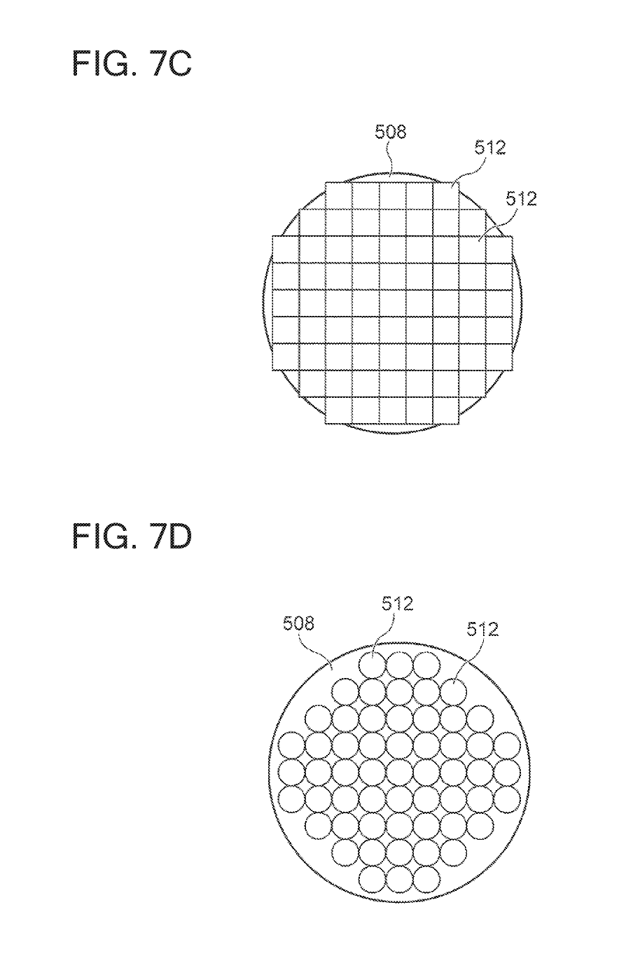

Thereafter, by applying the driving voltage to the piezoelectric element 512, the piezoelectric element 512 is deformed so as to make the catalyst 516 be in contact with or close to the processing target area of the substrate Wf. At this time, an AC voltage can be applied to the piezoelectric element 512. The piezoelectric element 512 vibrates (expands/contracts) at the frequency of the applied AC voltage. The frequency of the AC voltage to be applied may be set to any frequency. An AC voltage having a frequency corresponding to a natural frequency at which the catalyst holding base 514 holding the catalyst 516 resonates may be applied. An AC voltage pattern to be applied may be set to a rectangular wave, a sine wave or the like. A DC voltage may be applied to the piezoelectric element 512. FIG. 8 is a diagram showing an aspect that the CARE head 500 is approached to the processing target area of the substrate Wf and then the driving voltage is applied to the piezoelectric element 512 to bring the catalyst 516 into contact with the processing target surface of the substrate Wf. FIG. 8 shows a case where convex portions of a film formed on the surface of the substrate Wf are flattened. The left-side diagram of FIG. 8 shows a state before the CARE head 500 is approached to the processing target area of the substrate Wf and the driving voltage is applied to the piezoelectric element 512. The right-side diagram of FIG. 8 shows a state in which the CARE head 500 is approached to the processing target area of the substrate Wf and the driving voltage is applied to the piezoelectric element 512. As shown in FIG. 8, the piezoelectric element 512 is deformed by applying the driving voltage to the piezoelectric element 512, whereby the catalyst 516 can be brought into contact with or made close to the processing target area of the substrate Wf.

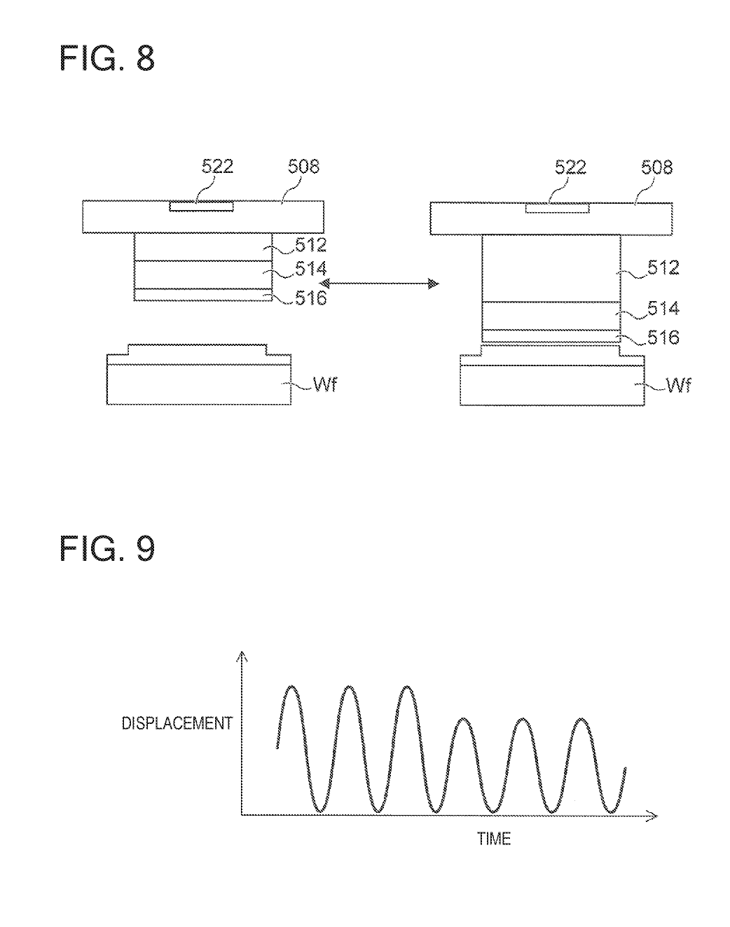

FIG. 9 is a graph showing a signal of the vibration sensor 522 when an AC voltage is applied to the piezoelectric element 512. In the graph of FIG. 9, the abscissa axis represents the time, and the ordinate axis represents the signal output of the vibration sensor 522. The signal output corresponds to the pressure in the case of the piezoelectric type vibration sensor 522, and corresponds to the distance between the base plate 508 and the head main body 506 in the case of the electrostatic capacitance type or eddy current type vibration sensor 522 as in the case of the embodiment shown in FIG. 3B. In general, the piezoelectric element varies in shape according to the magnitude of the driving voltage to be applied. When the catalyst 516 comes into contact with the substrate Wf, physical/mechanical restriction occurs in the deformation of the piezoelectric element 512. Therefore, when the magnitude of the driving voltage applied to the piezoelectric element 512 is increased while the signal corresponding to the displacement of the piezoelectric element 512 is monitored by the vibration sensor 522, the displacement does not vary beyond a certain value. At this time, it is determined that the catalyst 516 and the surface of the substrate Wf come into contact with each other. Alternatively, the CARE head 500 may be moved to the substrate Wf while an AC voltage having a predetermined magnitude is applied to the piezoelectric element 512. In this case, when the catalyst 516 is not in contact with the substrate Wf, a displacement corresponding to the driving voltage applied to the piezoelectric element 512 is output from the vibration sensor 522. When the catalyst 516 comes into contact with the substrate, the amplitude of the displacement which is observed via the vibration sensor 522 decreases (see FIG. 9) because restriction occurs in the deformation of the piezoelectric element 512. Therefore, it may be determined that the catalyst 516 and the substrate Wf come into contact with each other when the amplitude of the displacement observed via the vibration sensor 522 decreases. In the embodiment in which the piezoelectric element 512, the catalyst holding base 514 and the catalyst 516 are respectively divided into plural areas, determination as to the contact between the catalyst 516 and the substrate Wf may be performed for each area.

When it is determined that the piezoelectric element 512 and the substrate Wf can be brought into contact with each other or made close to each other by driving the piezoelectric element 512, the processing liquid for the CARE processing is supplied to the gap between the catalyst 516 and the surface of the substrate Wf. In the embodiment shown in FIG. 2, the processing liquid can be supplied from the processing liquid supply nozzle 702 provided outside the CARE head 500. However, in another embodiment, the processing liquid supply nozzle 702 may be provided inside the CARE head 500 to supply the processing liquid from the CARE head 500. For example, a pipe line for supplying the processing liquid from the rotating shaft 510 to the surface of the catalyst 516 may be provided to supply the processing liquid from the surface of the catalyst 516. For example, a structure disclosed in PTL 2 (WO2015/159973) may be adopted as the CARE head equipped with the pipe line for supplying the processing liquid from the rotating shaft 510 to the surface of the catalyst 516. The catalyst holding base 514 and the catalyst 516 may be structured to have a groove portion for uniformly supplying the processing liquid to the surface of the catalyst 516. The groove portion may comprise plural grooves arranged concentrically on the surface of the catalyst 516, grooves arranged lengthwise and widthwise in a lattice form, plural grooves extending radially from the center of the surface of the catalyst 516, a spirally extending groove or the like.

In the CARE reaction, the etching speed is changed by applying a voltage to the surface of the catalyst according to the selected catalyst material. Therefore, a voltage may be applied to the catalyst 516 together with the supply of the processing liquid.

The CARE reaction occurs by supplying the processing liquid under the state that the catalyst 516 is allowed to come into contact with the processing target area of the substrate Wf by driving the piezoelectric element 512. At this time, the catalyst 516 and the processing target area of the substrate Wf may be relatively moved. For example, the catalyst 516 and the processing target area of the substrate Wf can be relatively moved by moving the arm 600 of the CARE head 500 or rotating the stage 400 on which the substrate Wf is placed. Alternatively, the CARE head 500 may be rotated. The relative movement between the catalyst 516 and the processing target area of the substrate Wf is performed while vibrating the piezoelectric element 512. As described above, on the basis of the determination as to the contact between the catalyst 516 and the substrate Wf, the driving voltage to be applied to the piezoelectric element 512 is controlled so that the distance between the catalyst 516 and the processing target surface of the substrate Wf is equal to several tens nm or less, more preferably 10 nm or less for the maximum displacement of the piezoelectric element 512. On the basis of the determination as to the contact between the catalyst 516 and the substrate Wf, the amplitude of the driving voltage of the piezoelectric element 512 may be controlled, thereby controlling the contact amount between the catalyst 516 and the substrate Wf.

As described above, since the distance between the catalyst 516 and the processing target surface of the substrate Wf can be minutely controlled by the piezoelectric element 512, the contact amount or approaching (closeness) amount of the surface of the catalyst 516 to the processing target surface can be reduced. Therefore, a mechanical damage imposed on the surface of the catalyst 516 can be reduced, and the deterioration of the catalyst can be mitigated.

After the CARE processing is executed, the processed substrate Wf is carried to the cleaning apparatus 1300 by the carrying mechanism 1500 to clean the substrate Wf. The cleaning of the substrate Wf can be performed by any publicly-known method. After the substrate Wf has been cleaned, the substrate Wf is carried to the drying apparatus 1400 by the carrying mechanism 1500. The drying of the substrate Wf can be performed by any publicly-known method. After the substrate Wf has been dried, the substrate Wf is arranged at a predetermined position by the carrying mechanism 1500. The CARE processing by the substrate processing apparatus 1000 may be executed after the CMP processing is executed by the CMP apparatus 1200 of the substrate processing system 1100.

In the substrate processing apparatus 1000 disclosed in the present specification, various kinds of substrates can be processed by using various catalysts and processing liquid. Examples of the processing target area of the substrate Wf contain an insulating film represented by SiO₂ or Low-k material, wiring metal represented by Cu or W, barrier metal represented by Ta, Ti, TaN, TiN, Co or the like, or group III-V materials represented by GaAs or the like. The material of the catalyst 516 may include, for example, noble metal, transition metal, a ceramic-based solid catalyst, a basic solid catalyst, an acidic solid catalyst or the like. The processing liquid may include, for example, oxygen dissolved water, ozone water, acid, alkaline solution, H₂O₂ water, hydrofluoric acid solution or the like. The catalyst 516 and the processing liquid may be appropriately set according to the material of the processing target area of the substrate Wf. For example, when the material of the processing target area is Cu, an acidic solid catalyst may be used as the catalyst 516, and ozone water may be used as the processing liquid. When the material of the processing target area is SiO₂, platinum or nickel may be used as the catalyst 516, and acid may be used as the processing liquid. When the material of the processing target area is group III-V metal (for example, GaAs), iron may be used as the catalyst 516, and H₂O₂ water may be used as the processing liquid.

The embodiments of the present invention have been described based on some examples. However, the foregoing embodiments of the present invention are provided to make the present invention easily understandable, and do not limit the present invention. It is needless to say that the present invention may be modified and improved without departing from the subject matter thereof, and contain equivalents thereof. Furthermore, any combination or omission of the respective constituent elements recited in claims and described in the specification is possible within a range where at least a part of the foregoing problem can be solved or at least a part of the foregoing effect can be obtained.

### REFERENCE SIGNS LIST

400 stage
500 CARE head
502 gimbal mechanism
504 outer peripheral member
506 head main body
508 base plate
510 shaft
512 piezoelectric element
514 catalyst holding base
516 catalyst
518 catalyst electrode
520 counter electrode
522 vibration sensor
550 spring
600 holding arm
602 vertical driving mechanism
620 lateral driving mechanism
702 processing liquid supply nozzle
900 control device
1000 substrate processing apparatus
1100 substrate processing system
1200 CMP apparatus
1300 cleaning apparatus
1400 drying apparatus
1500 carrying mechanism
Wf substrate

What is claimed is:

1. A substrate processing apparatus for making a catalyst and a substrate close to each other or be in contact with each other in the presence of processing liquid to etch a processing target area of the substrate comprising:
a substrate holder for holding a substrate; and
a catalyst holder for holding a catalyst, wherein the catalyst holder comprises:
a base plate having high rigidity;
a piezoelectric element arranged to be adjacent to the base plate;
a catalyst holding base having high rigidity arranged to be adjacent to the piezoelectric element; and
a catalyst held by the catalyst holding base, and wherein the substrate processing apparatus further comprises a control device for controlling a driving voltage to be applied to the piezoelectric element.

2. The substrate processing apparatus according to claim 1, wherein the catalyst holder has a first area and a second area, the first area includes a first catalyst, a first catalyst holding base, and a first piezoelectric element, the second area includes a second catalyst, a second catalyst holding base, and a second piezoelectric element, and the control device is configured to be capable of applying a driving voltage to each of the first piezoelectric element and the second piezoelectric element independently of each other.

3. The substrate processing apparatus according to claim 1, wherein the control device is configured to apply, to the piezoelectric element, a driving voltage having a frequency for resonating the catalyst holding base and the catalyst.

4. The substrate processing apparatus according to claim 1, wherein the catalyst holder includes a vibration sensor for monitoring vibration amplitude of the piezoelectric element.

5. The substrate processing apparatus according to claim 1, further comprising a first driving mechanism for moving the catalyst holder in a direction to the substrate holder.

6. The substrate processing apparatus according to claim 1, further comprising a second driving mechanism for moving the catalyst holder in a direction parallel to a substrate holding face of the substrate holder.

7. The substrate processing apparatus according to claim 6, wherein the movement of the catalyst holder by the second driving mechanism contains at least one of a rotational movement, a rectilinear movement and a combination movement of the rotational movement and the rectilinear movement.

8. The substrate processing apparatus according to claim 1, further comprising a third driving mechanism for moving the substrate holder in a direction parallel to a substrate holding face of the substrate holder.

9. The substrate processing apparatus according to claim 8, wherein the movement of the catalyst holder by the third driving mechanism contains at least one of a rotational movement, a rectilinear movement and a combination movement of the rotational movement and the rectilinear movement.

10. A substrate processing system comprising:
the substrate processing apparatus according to claim 1;
a cleaning apparatus for cleaning the substrate after the processing in the substrate processing apparatus;
a drying apparatus for drying the substrate after the cleaning in the cleaning apparatus;
a carrying mechanism for carrying the substrate in the substrate processing system; and
a control device for controlling operations of the substrate processing apparatus, the cleaning apparatus, the drying apparatus and the carrying mechanism.

11. The substrate processing system according to claim 10, further comprising a CMP apparatus for performing CMP processing on the substrate.
